(19) United States
(12) Patent Application Publication
(10) Pub. No.: US 2026/0005120 A1
(43) Pub. Date: Jan. 1, 2026

(54) PACKAGE SUBSTRATE AND SEMICONDUCTOR PACKAGE INCLUDING THE SAME

(71) Applicant: Samsung Electronics Co., Ltd., Suwon-si (KR)

(72) Inventor: Jinhyung JUNG, Suwon-si (KR)

(21) Appl. No.: 19/016,882

(22) Filed: Jan. 10, 2025

(30) Foreign Application Priority Data
Jun. 27, 2024 (KR) 10-2024-0084734

(51) Int. Cl. H01L 23/498; H01L 23/00; H01L 25/065

(52) U.S. Cl. CPC H01L 23/49838; H01L 23/49866; H01L 24/48; H01L 25/0652; H01L 2224/48145; H01L 2224/48228; H01L 2924/1431

(57) ABSTRACT

Provided is a package substrate that includes a substrate body part, a bonding pad, and a connection wiring that is connected to the bonding pad in a first direction parallel to a surface of the substrate body part. At least a portion of the bonding pad is embedded in the substrate body part. At least a portion of the connection wiring is embedded in the substrate body part. The bonding pad includes an embedding layer embedded in the substrate body part, a first metal layer formed on the embedding layer, and a second metal layer formed on the first metal layer. The first metal layer has an upper surface that is flat.

### CROSS-REFERENCE TO RELATED APPLICATION

This application is based on and claims priority under 35 U.S.C. § 119 to Korean Patent Application No. 10-2024-0084734, filed on Jun. 27, 2024, in the Korean Intellectual Property Office, the disclosure of which is incorporated herein by reference.

### BACKGROUND

Example embodiments relate to a package substrate and a semiconductor package including the same.

A semiconductor package is an integrated circuit chip implemented in a form suitable for use in electronic products. In general, a semiconductor chip is mounted on a printed circuit board (PCB) and wires or bumps are connected to the bonding pads of the PCB in a semiconductor package in order to electrically connect the PCB and the semiconductor chip. As miniaturization and high performance progress for semiconductor packages, the reliability of the bonding pads on the PCB is required.

### SUMMARY

An aspect provides a package substrate by which the structural stability is improved.

Another aspect provides a semiconductor package by which stability of wire bonding is improved.

Another aspect also provides a semiconductor package by which electrical reliability is improved.

The technical tasks to be achieved by the present example embodiments are not limited to the technical tasks described above, and other technical tasks may be inferred from the following example embodiments by those skilled in the art.

According to an aspect, there is provided a package substrate including a substrate body part, a bonding, pad at least a portion of which is embedded in the substrate body part, and a connection wiring, at least a portion of which is embedded in the substrate body part, and that is connected to the bonding pad in a first direction parallel to a surface of the substrate body part, wherein the bonding pad includes an embedding layer embedded in the substrate body part, a first metal layer formed on the embedding layer and a second metal layer formed on the first metal layer, and the first metal layer has an upper surface that is flat.

According to another aspect, there is provided a semiconductor package including a package substrate and a semiconductor chip that is wire-bonded on the package substrate, wherein the package substrate includes a substrate body part and a bonding pad that disposed on the substrate body part and connected to the semiconductor chip by a wire, the bonding pad includes an embedding layer embedded in the substrate body part, a first metal layer on the embedding layer and a second metal layer on the first metal layer, and a side wall of the first metal layer and a side wall of the second metal layer are coplanar.

According to another aspect, there is provided a package substrate including a substrate body part, a connection wiring embedded in the substrate body part, a bonding pad that is connected to the connection wiring in a first direction that is parallel to a surface of the substrate body part and a protection layer that is disposed on the substrate body part, and includes an opening that exposes an upper surface of the bonding pad, wherein the bonding pad includes an embedding layer embedded in the substrate body part, a first metal layer on the embedding layer and a second metal layer on the first metal layer, wherein the protection layer has an upper surface that is disposed at a level that is higher than a level of an upper surface of the second metal layer, an upper surface of the first metal layer and an upper surface of the second metal layer are flat, in a second direction that is parallel to the surface of the substrate body part and intersects the first direction, a width of the first metal layer and a width of the second metal layer are identical, and the width of the first metal layer is greater than a width of the embedding layer.

Additional aspects of example embodiments will be set forth in part in the description which follows and, in part, will be apparent from the description, or may be learned by practice of the disclosure.

According to example embodiments, it is possible to improve the structural stability of a package substrate.

According to example embodiments, it is possible to improve the stability of wire bonding in a semiconductor package.

According to example embodiments, it is possible to improve the electrical reliability of a semiconductor package.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a schematic plan view illustrating a package substrate according to an example embodiment;

FIG. 2 is an enlarged view illustrating a portion P of FIG. 1;

FIG. 3 is a cross-sectional view taken along line A-A of FIG. 1;

FIG. 4 is a cross-sectional view taken along line B-B of FIG. 1;

FIG. 5 is a drawing for explaining a package substrate according an example embodiment;

FIGS. 6 to 10 are drawings illustrating an intermediate operation for explaining a method for manufacturing a package substrate according an example embodiment;

FIG. 11 is a plan view illustrating a semiconductor package according to an example embodiment;

FIG. 12 is a cross-sectional view taken along line C-C of FIG. 11; and

FIGS. 13 and 14 are enlarged views for explaining a portion Q of FIG. 12.

### DETAILED DESCRIPTION

Prior to the detailed description of the present disclosure, terms or words used in the specification and claims should not be construed as limited to their common or dictionary meanings. Further, the terms or words should be interpreted with meaning and concept consistent with the technical idea of the present disclosure based on the principle that the inventor may appropriately define the concept of terms in order to explain his or her invention in the best way. The example embodiments described in this specification and the configurations shown in the drawings are only the most preferred embodiments of the present disclosure, and do not necessarily represent the entire technical idea of the present disclosure. Accordingly, at the time of filing the present disclosure, there may be various equivalents and modifications that can replace them.

In the following description, singular expressions include plural expressions unless the context clearly dictates otherwise. It will be understood that, when an element (for example, a first element) is “(operatively or communicatively) coupled with/to” or “connected to” another element (for example, a second element), the element may be directly coupled with/to another element, and there may be an intervening element (for example, a third element) between the element and another element. When an element is referred to as “contacting,” “in contact with,” or “contact” another element, there are no intervening elements present at the point of contact. The terms “have,” “may have,” “include,” and “may include” as used herein indicate the presence of corresponding features (for example, elements such as numerical values, functions, operations, or parts), and do not preclude the presence of additional features.

Further, in the following description, expressions such as an upper side, top, a lower side, bottom, a side, front and a back side are expressed based on the direction shown in the drawing. If the direction of the object changes, it may be expressed differently. The shapes and sizes of elements in the drawings may be exaggerated for clearer explanation.

Terms such as “same,” “equal,” “planar,” or “coplanar,” as used herein encompass identicality or near identicality including variations that may occur, for example, due to manufacturing processes. The term “substantially” may be used herein to emphasize this meaning, unless the context or other statements indicate otherwise.

Throughout the specification, when a component is described as “including,” “may include,” or “includes” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

Hereinafter, example embodiments of the present disclosure will be described in detail with reference to the attached drawings.

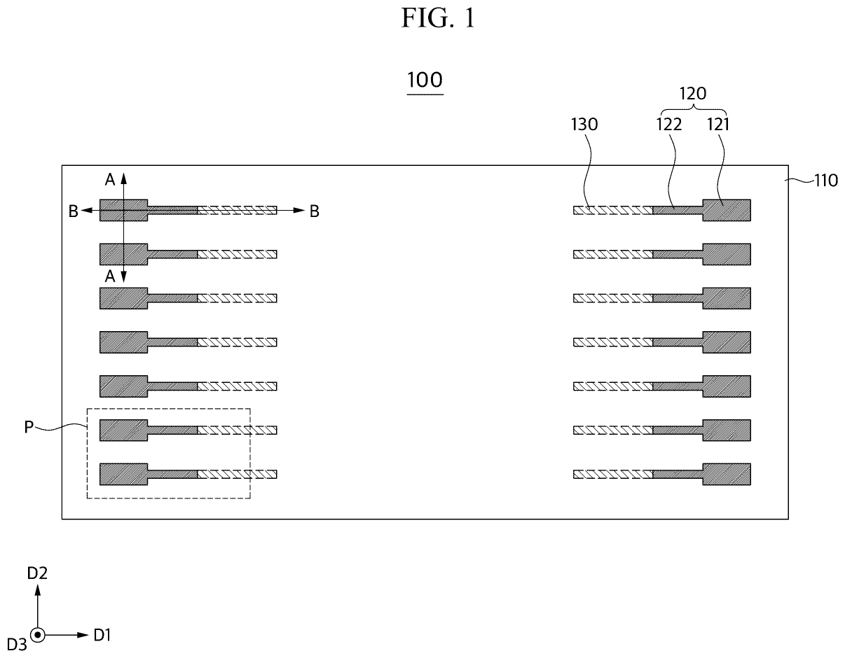

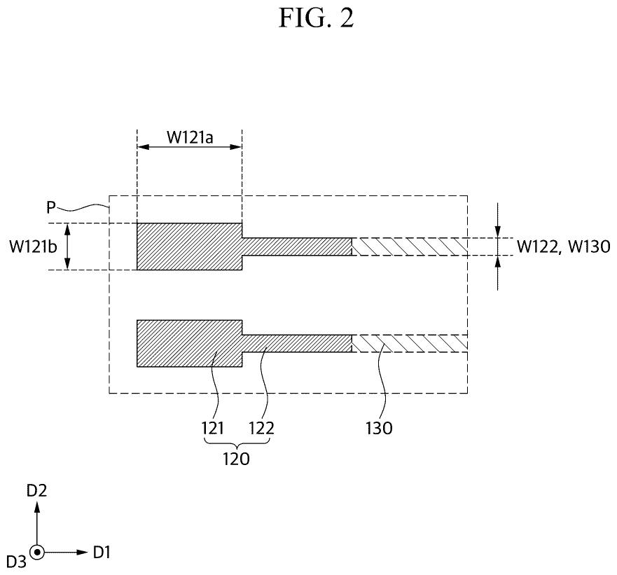

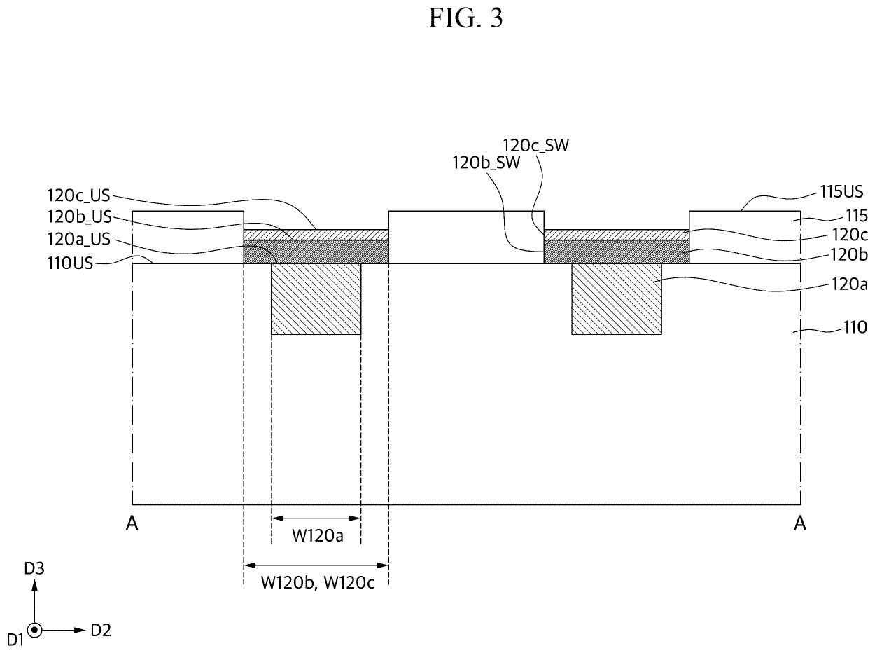

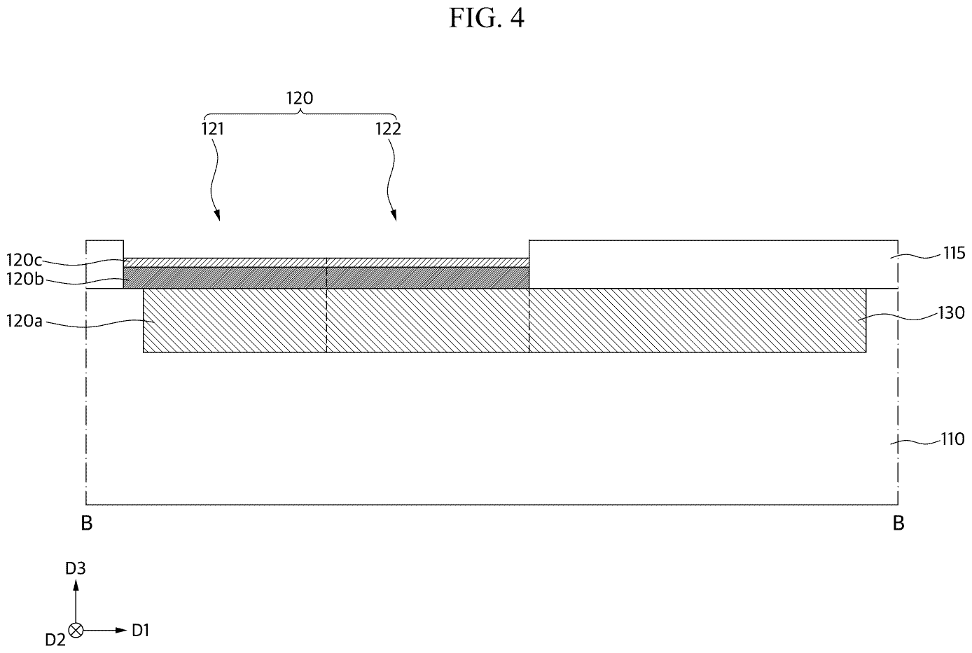

FIG. 1 is a schematic plan view illustrating a package substrate according to an example embodiment. FIG. 2 is an enlarged view illustrating the portion P of FIG. 1. FIG. 3 is a cross-sectional view taken along line A-A of FIG. 1. FIG. 4 is a cross-sectional view taken along line B-B of FIG. 1.

Referring to FIGS. 1 to 4, a package substrate 100 may include a substrate body part 110, a bonding pad 120 and a connection wiring 130.

According to some example embodiments, the package substrate 100 may be a distribution structure for the package. For example, the package substrate 100 may be a PCB, a ceramic substrate or an interposer. Alternatively, the package substrate 100 may be a distribution structure for a wafer level package (WLP) manufactured at the wafer level. The package substrate 100 may be a semiconductor chip including a semiconductor device. The package substrate 100 may function as a support substrate for a semiconductor package.

In some example embodiments, the package substrate 100 may be a glass substrate, a ceramic substrate or a plastic substrate, but the package substrate 100 is not limited thereto. For example, the package substrate 100 may include a resin impregnated in a core material such as glass fiber, glass cloth and glass fabric together with an inorganic filler. For example, prepreg, an ajinomoto build-up film (ABF), FR-4, or bismaleimide triazine (BT) may be included.

According to some example embodiments, the package substrate 100 may include bulk silicon or a silicon-on-insulator (SOI). In another example embodiment, the package substrate 100 may be a silicon substrate. In another example embodiment, the package substrate 100 may include silicon germanium, a silicon germanium on insulator (SGOI), indium antimonide, lead telluride, indium arsenide, indium phosphide, gallium arsenide or gallium antimonide. However, the package substrate 100 is not limited thereto.

According to some example embodiments, the package substrate 100 may include a doped well or a structure doped with impurities. The package substrate 100 may have various device isolation structures, such as a shallow trench isolation (STI) structure.

According to some example embodiments, if the package substrate 100 is a PCB, the substrate body part 110 may be made of at least one material selected from phenol resin, epoxy resin and polyimide. The package substrate 100 may include at least one material selected from tetrafunctional epoxy, polyphenylene ether, epoxy/polyphenylene oxide, bismaleimide triazine (BT), thermount, cyanate ester and liquid crystal polymer.

In some example embodiments, the substrate body part 110 may include a photoimageable dielectric material. For example, the substrate body part 110 may include a photosensitive polymer. For example, the photosensitive polymer may be formed of at least one of a photosensitive polyimide, a polybenzoxazole, a phenol-based polymer and a benzocyclobutene-based polymer. In another example embodiment, the substrate body part 110 may be formed of a silicon oxide film, a silicon nitride film or a silicon oxynitride film.

According to some example embodiments, the package substrate 100 may include a protection layer 115 placed on the substrate body part 110. The protection layer 115 may cover the surface of the substrate body part 110. The protection layer 115 may include an opening that exposes the second metal layer 120c. For example, the protection layer 115 may be a passivation film formed on the surface of the substrate body part 110. The protection layer 115 may include solder resist. However, the present disclosure is not limited thereto. The protection layer 115 formed on the surface of the substrate body part 110 may protect other structures such as the bonding pad 120 and the connection wiring 130 from external impact or moisture.

According to some example embodiments, the bonding pad 120 may include a bonding part 121 and a connection part 122. Each of the bonding part 121 and the connection part 122 may include an embedding layer 120a, a first metal layer 120b and a second metal layer 120c.

According to some example embodiments, the bonding part 121 may be separated from the connection wiring 130 having the connection part 122 therebetween. From a plan view, the bonding part 121 may have a larger area than the connection part 122. In a plan view, the substrate body part 110 may extend in a first direction D1 and a second direction D2, which intersects the first direction D1. In the second direction D2, the width of the bonding part W121b may be greater than the width of the connection part W122. Specifically, the width of the bonding part W121b and the width of the connection part W122 may indicate the widths of the first metal layer 120b and the second metal layer 120c each of which is included in the bonding part 121 and the connection part 122. Further, in the second direction D2, the maximum width of the bonding pad 120 may be greater than the maximum width of the connection wiring 130. For example, from the plan view, the area of the bonding pad 120 may be larger than the area of the connection wiring 130. In the second direction D2, through the bonding pad 120 which has a width greater than the maximum width of the connection wiring 130, the wire bonding may be performed stably.

According to some example embodiments, the connection part 122 may be placed between the bonding part 121 and the connection wiring 130. The connection part 122 may connect the bonding part 121 and the connection wiring 130.

According to some example embodiments, the width of the bonding part W121a in the first direction D1 may be greater than the width of the bonding part W121b in the second direction D2. For example, from the plan view, the bonding part 121 may have a rectangular shape with a long side in the first direction D1 and a short side in the second direction D2. Specifically, the width W121a and the width W121b of the bonding part 121 may indicate the width of the first metal layer 120b and the width of the second metal layer 120c included in the bonding part 121. Here, the first direction D1 may be the direction in which the bonding pad 120 and the connection wiring 130 are connected. For example, the first direction D1 may be the direction in which the connection wiring 130 extends that is connected to the bonding pad 120. The first direction D1 may be the direction in which the bonding part 121, the connection part 122 and the connection wiring 130 are placed. The first direction D1 may be a direction parallel to the surface of the substrate body part 110.

For example, FIG. 1 illustrates that the bonding part 121 has a rectangular shape in the plan view. However, the present disclosure is not limited thereto. In another example embodiment, the bonding part 121 may be an ellipse having a major axis in the first direction D1 and a minor axis in the second direction D2.

According to some example embodiments, at least a portion of the bonding pad 120 may be embedded in the substrate body part 110. For example, the embedding layer 120a of the bonding pad 120 may be embedded in the substrate body part 110.

According to some example embodiments, at least a portion of the bonding pad 120 may be exposed from the substrate body part 110. For example, the second metal layer 120c of the bonding pad 120 may be exposed from the surface of the substrate body part 110. The first metal layer 120b and the second metal layer 120c may not be embedded in the substrate body part 110, and may be placed on the surface of the substrate body part 110. The bonding pad 120 may be placed in the substrate body part 110 in the second direction D2. The embedding layer 120a of the bonding pad 120 may be placed in (i.e., embedded in) the substrate body part 110 in the third direction D3. The third direction D3 may be perpendicular to the first direction D1 and the second direction D2. The bonding pads 120 may be spaced at regular intervals in the second direction D2. The second direction D2 may be the direction in which bonding pads 120 are placed.

According to some example embodiments, the bonding pads 120 may be electrically connected to semiconductor chips placed on the package substrate 100. The bonding pads 120 may electrically connect devices such as semiconductor chips mounted on the package substrate 100 to the package substrate 100. For example, a wire that electrically connects a semiconductor chip and the package substrate 100 may be bonded on the bonding part 121 of the bonding pad 120.

According to some example embodiments, the bonding pad 120 may include a conductive material. For example, the bonding pad 120 may include copper (Cu), aluminum (Al), silver (Ag), tin (Sn), gold (Au), nickel (Ni), lead (Pb), titanium (Ti), or alloys thereof. However, the bonding pad 120 is not limited thereto.

According to some example embodiments, the bonding pad 120 may include the embedding layer 120a, the first metal layer 120b and the second metal layer 120c. The embedding layer 120a, the first metal layer 120b and the second metal layer 120c may be sequentially stacked in the third direction D3.

According to some example embodiments, the embedding layer 120a may be placed in the substrate body part 110. The embedding layer 120a may be formed by being embedded in the substrate body part 110. An upper surface of the embedding layer 120a_US may be coplanar with an upper surface 110US of the substrate body part 110. For example, the embedding layer 120a may not protrude beyond the upper surface 110US of the substrate body part. The side wall of the embedding layer 120a may be surrounded by the substrate body part 110.

According to some example embodiments, by the upper surface of the embedding layer 120a_US being coplanar with the upper surface 110US of the substrate body part 110, the thickness of the first metal layer 120b and the second metal layer 120c formed after the embedding layer 120a may be stably controlled. For example, when the upper surface of the embedding layer 120a_US is placed on a level that is lower than a level of the upper surface 110US of the substrate body part 110, if the space formed by the step between the upper surface of the embedding layer 120a_US and the upper surface 110US of the substrate body part 110 is filled with the first metal layer 120b, it may be difficult to form the first metal layer 120b with a consistent thickness.

Therefore, when the first metal layer 120b is formed on the embedding layer 120a having an upper surface that is coplanar with the upper surface 110US of the substrate body part 110, the first metal layer 120b may be formed with a constant thickness. When the thickness of the first metal layer 120b is consistent, the thickness of the second metal layer 120c formed on the first metal layer 120b may also be formed consistently.

According to some example embodiments, the embedding layer 120a may be connected to the connection wiring 130. More specifically, the embedding layer 120a may be formed integrally with the connection wiring 130. For example, the embedding layer 120a may be formed in the same process operation as the connection wiring 130.

According to some example embodiments, the first metal layer 120b may be placed on and in contact with the embedding layer 120a. The first metal layer 120b may cover the upper surface of the embedding layer 120a_US. The first metal layer 120b may be placed between the embedding layer 120a and the second metal layer 120c. The thickness of the first metal layer 120b may be greater than the thickness of the second metal layer 120c. The thickness of the first metal layer 120b may be the distance from the upper surface of the embedding layer 120a_US to an upper surface of the first metal layer 120b_US. The thickness of the second metal layer 120c may be the distance from the upper surface of the first metal layer 120b_US to an upper surface of the second metal layer 120c_US. However, the present disclosure is not limited thereto. For example, the thickness of the first metal layer 120b may be less than the thickness of the second metal layer 120c.

According to some example embodiments, the first metal layer 120b may be placed on the substrate body part 110. For example, based on the bottom surface of the substrate body part 110, the upper surface of the first metal layer 120b_US may be placed on a level higher than a level of the upper surface 110US of the substrate body part. The first metal layer 120b may not be surrounded by the substrate body part 110. The first metal layer 120b may not be embedded in the substrate body part 110. The first metal layer 120b may cover at least a portion of the upper surface 110US of the substrate body part.

According to some example embodiments, the first metal layer 120b may be surrounded by the protection layer 115. The protection layer 115 may be disposed on the substrate body part 110. The first metal layer 120b may be surrounded by the protection layer 115 on the substrate body part 110. A side wall of the first metal layer 120b_SW may contact the protection layer 115. The side wall of the first metal layer 120b_SW may intersect the substrate body part 110.

According to some example embodiments, the second metal layer 120c may be placed on the embedding layer 120a and the first metal layer 120b. The second metal layer 120c may cover the embedding layer 120a and the first metal layer 120b. Specifically, the second metal layer 120c may be separated from the embedding layer 120a having the first metal layer 120b therebetween.

According to some example embodiments, the second metal layer 120c may be placed on and in contact with the first metal layer 120b. The second metal layer 120c may cover the upper surface of the first metal layer 120b_US. The second metal layer 120c may be placed on the substrate body part 110. For example, based on the bottom surface of the substrate body part 110, the upper surface of the second metal layer 120c_US may be placed to be on a level that is higher than a level of the upper surface 110US of the substrate body part. The second metal layer 120c may not be surrounded by the substrate body part 110. The second metal layer 120c may not be embedded in the substrate body part 110.

According to some example embodiments, the second metal layer 120c may be surrounded by the protection layer 115. The protection layer 115 may be disposed on the substrate body part 110. The second metal layer 120c may be surrounded by the protection layer 115 on the substrate body part 110. A side wall of the second metal layer 120c_SW may come into contact with the protection layer 115. The side wall of the second metal layer 120c_SW may be coplanar with the side wall of the first metal layer 120b_SW.

According to some example embodiments, based on the upper surface 110US of the substrate body part, the upper surface of the second metal layer 120c_US may be placed on a level that is lower than a level of an upper surface of the protection layer 115US. For example, the combined thickness of the first metal layer 120b and the second metal layer 120c may be less than the thickness of the protection layer 115. The protection layer 115 may protrude further from the substrate body part 110 than the second metal layer 120c. By the protection layer 115 protruding further than the second metal layer 120c, the upper surface of the second metal layer 120c_US may be protected from the outside.

According to some example embodiments, in the second direction D2, the width of the first metal layer W120b and the width of the second metal layer W120c may be greater than the width of the embedding layer W120a. The embedding layer 120a having a width smaller than the width of the first metal layer 120b and the second metal layer 120c may reduce resistance with other wiring placed on the substrate body part 110. The first metal layer 120b and the second metal layer 120c having a width larger than the width of the embedding layer 120a may have sufficient areas for the stable wire bonding when the wire is bonded.

According to some example embodiments, in the first direction D1, the width of the embedding layer 120a may be smaller than the width of the first metal layer 120b and the width of the second metal layer 120c. As illustrated in FIG. 4, in the cross-section cut in the first direction D1, a side wall of the embedding layer 120a may not be coplanar with a side wall of the first metal layer 120b and a side wall of the second metal layer 120c. The first metal layer 120b and the second metal layer 120c in the bonding part 121 may include a portion overlapping the embedding layer 120a and a portion overlapping the substrate body part 110 in the third direction D3.

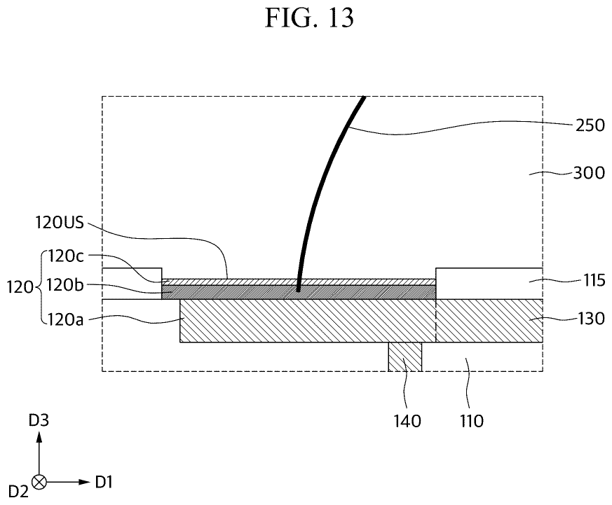

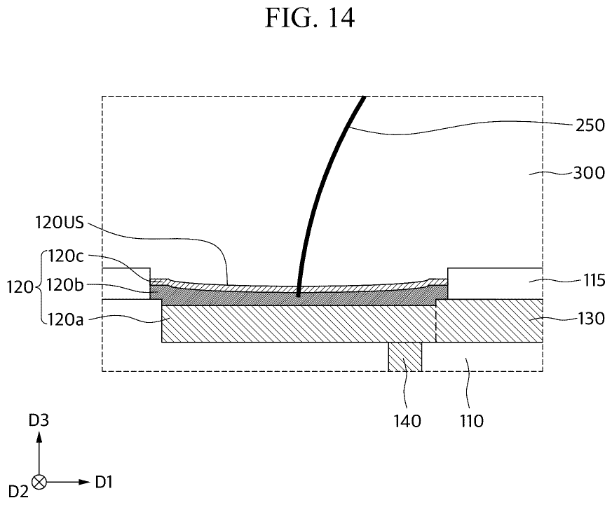

As illustrated in FIGS. 13 and 14, for example, according to some example embodiments, when the wire is bonded to the bonding pad 120, the wire may contact the first metal layer 120b and the second metal layer 120c, but not contact the embedding layer 120a. The embedding layer 120a may electrically connect the first metal layer 120b and the second metal layer 120c with the connection wiring 130. When the embedding layer 120a overlaps and contacts the first metal layer 120b and the second metal layer 120c by a predetermined degree or more, electrical signals may be stably transmitted between the first metal layer 120b and the second metal layer 120c, and the connection wiring 130. Therefore, by adjusting the degree to which the first metal layer 120b and the second metal layer 120c overlap the embedding layer 120a in the third direction D3, relative positions at which wires are bonded for the connection wiring 130 may be controlled.

According to some example embodiments, the embedding layer 120a, the first metal layer 120b and the second metal layer 120c may include different materials, respectively. For example, the embedding layer 120a may include copper (Cu). For example, the first metal layer 120b may include nickel (Ni). For example, the second metal layer 120c may include gold (Au).

According to some example embodiments, the upper surface of the first metal layer 120b_US and the upper surface of the second metal layer 120c_US may be flat. For example, the upper surface of the first metal layer 120b_US and the upper surface of the second metal layer 120c_US may be placed parallel to the upper surface 110US of the substrate body part. When the upper surface of the first metal layer 120b_US and the upper surface of the second metal layer 120c_US are formed flat, not curved, not like a convex shape toward the top from the substrate body part 110, the accuracy of pitch control of the first metal layer 120b and the second metal layer 120c may be improved.

According to some example embodiments, the connection wiring 130 may be connected to the embedding layer 120a of the bonding pad 120. The connection wiring 130 may be embedded within the substrate body part 110. The connection wiring 130 may overlap the protection layer 115 in the third direction D3. The third direction D3 may be the thickness direction of the substrate body part 110. The upper surface of the connection wiring 130 may be covered by the protection layer 115.

According to some example embodiments, the connection wiring 130 may electrically connect the bonding pad 120 and a redistribution layer (including a redistribution line 140) placed in the substrate body part 110. The bonding pad 120, to which the wire is bonded, may be exposed from the protection layer 115, and the connection wiring 130, which is electrically connected to the bonding pad 120 and transmits signals to the redistribution layer, may be protected by the protection layer 115. Thus, the electrical stability may be improved.

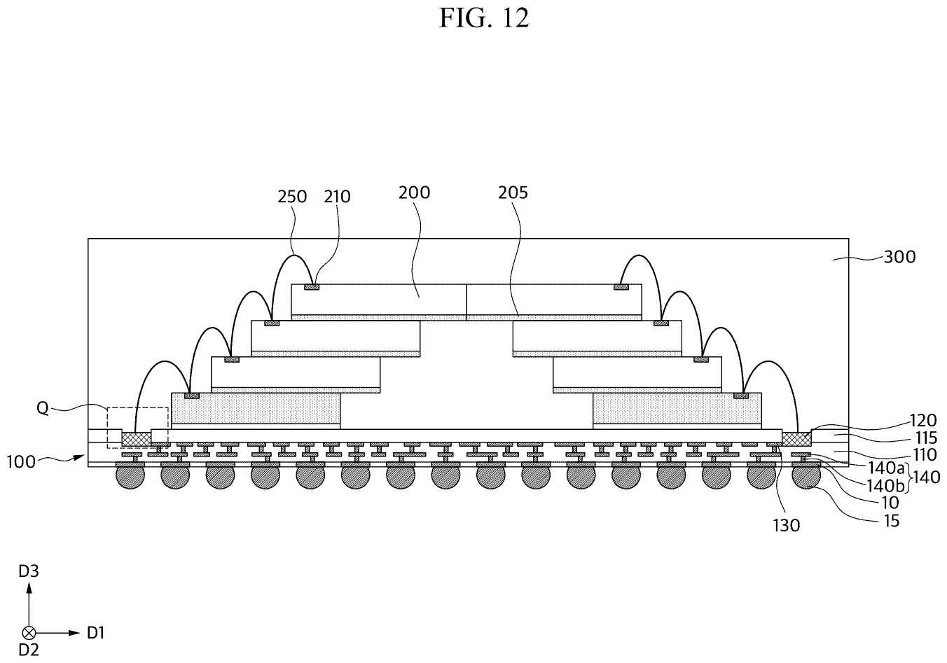

FIGS. 1 to 4 illustrate that the connection wiring 130 is not connected to any other element other than the bonding pad 120. However, FIGS. 1 to 4 are drawings simplified for convenience of explanation. Accordingly, the connection wiring 130 may electrically connect another distribution structure and the bonding pad 120 placed in the substrate body part 110 as shown, for example, in FIG. 12.

According to some example embodiments, the connection wiring 130 may include copper (Cu), but is not limited thereto. For example, the connection wiring 130 may include aluminum (Al), silver (Ag), tin (Sn), gold (Au), nickel (Ni), lead (Pb), titanium (Ti), or alloys thereof.

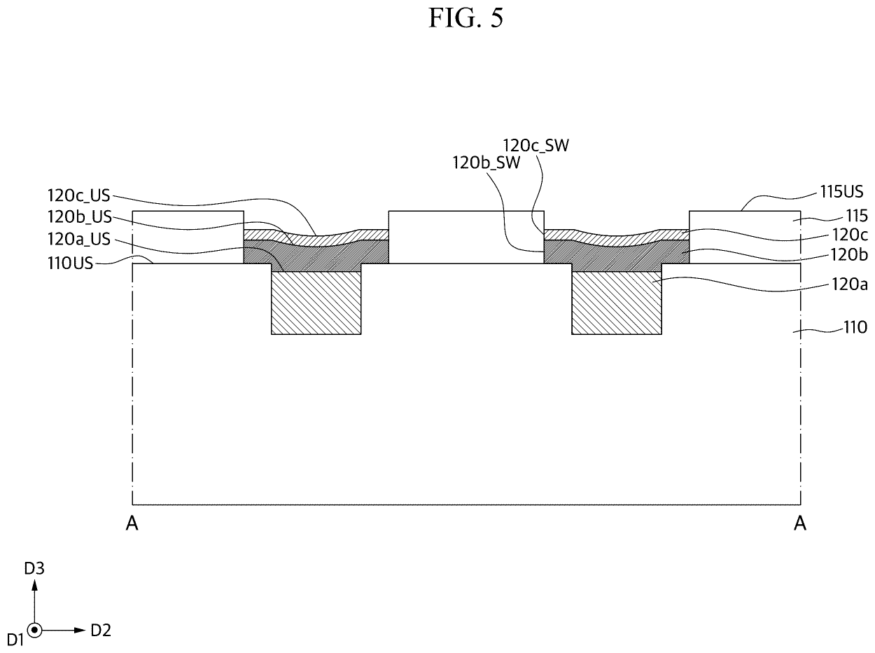

FIG. 5 is a drawing for explaining a package substrate according an example embodiment. For convenience of explanation, differences from those described with reference to FIGS. 1 to 4 will be mainly described.

Referring to FIG. 5, based on the upper surface 110US of the substrate body part 110, the upper surface of the embedding layer 120a_US may be placed on a level that is lower than a level of the upper surface 110US of the substrate body part 110. Accordingly, a step may be formed between the upper surface of the embedding layer 120a_US and the upper surface 110US of the substrate body part 110. A first portion of the first metal layer 120b may extend below the upper surface 110US of the substrate body part 110 and contact the upper surface of the embedding layer 120a_US. A second portion of the first metal layer 120b may contact the upper surface 110US of the substrate body part 110. The width of the first portion of the first metal layer 120b in the second direction D2 may be the same as the width of the embedding layer 120a in the second direction D2.

According to some example embodiments, the upper surface of the first metal layer 120b_US may be formed concavely downward toward the embedding layer 120a. By the first metal layer 120b being formed along the step between the upper surface of the embedding layer 120a_US and the upper surface 110US of the substrate body part 110, the upper surface of the first metal layer 120b_US may have a shape that is shallowly recessed toward the upper surface of the embedding layer 120a_US.

According to some example embodiments, by the second metal layer 120c formed on the first metal layer 120b being formed along the upper surface of the first metal layer 120b_US, the second metal layer 120c may have a shape that is shallowly recessed toward the upper surface of the first metal layer 120b_US. For example, the upper surface of the second metal layer 120c_US may also be formed concavely downward toward the upper surface of the first metal layer 120b_US.

According to some example embodiments, when compared to the case where the upper surface of the first metal layer 120b_US and the upper surface of the second metal layer 120c_US are flat, if the upper surface of the first metal layer 120b_US and the upper surface of the second metal layer 120c_US are concave downward toward the substrate body part 110, areas of the upper surface of the first metal layer 120b_US and the upper surface of the second metal layer 120c_US may increase. Therefore, the wire may be stably bonded to the first metal layer 120b and the second metal layer 120c. Further, since the upper surface of the first metal layer 120b_US and the upper surface of the second metal layer 120c_US are placed lower than the upper surface of the protection layer 115US, a risk that a structure like a ball neck formed when wires are bonded to the first metal layer 120b and the second metal layer 120c protrudes more outward than the protection layer 115 may be reduced.

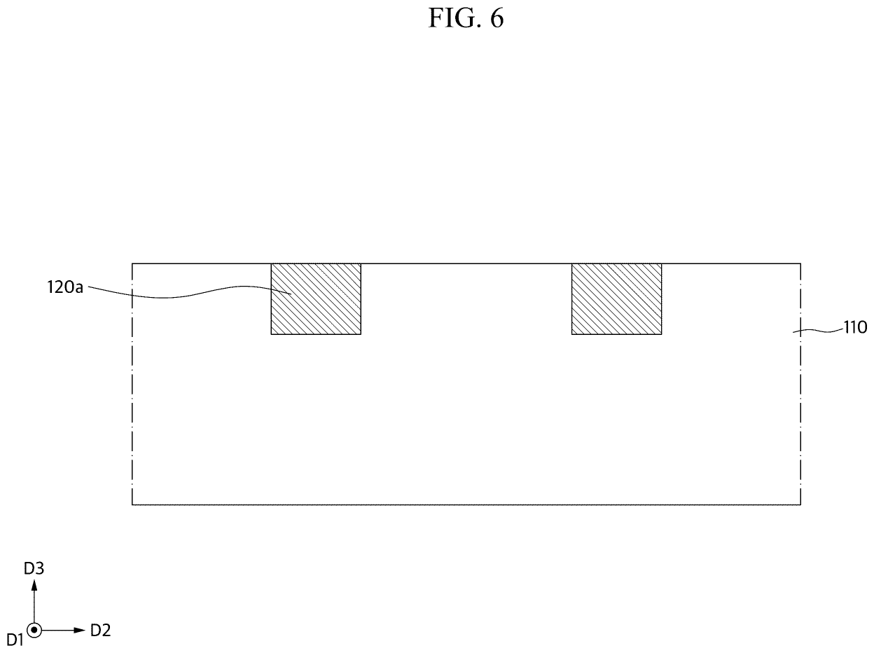

FIGS. 6 to 10 are drawings illustrating an intermediate operation for explaining a method for manufacturing a package substrate according to an example embodiment.

Referring to FIG. 6, the embedding layer 120a may be formed within the substrate body part 110. Side and bottom surfaces of the embedding layer 120a may be surrounded by the substrate body part 110. A top surface of the embedding layer 120a may be exposed (i.e., not covered by the substrate body part 110). The embedding layer 120a may be formed within the substrate body part 110.

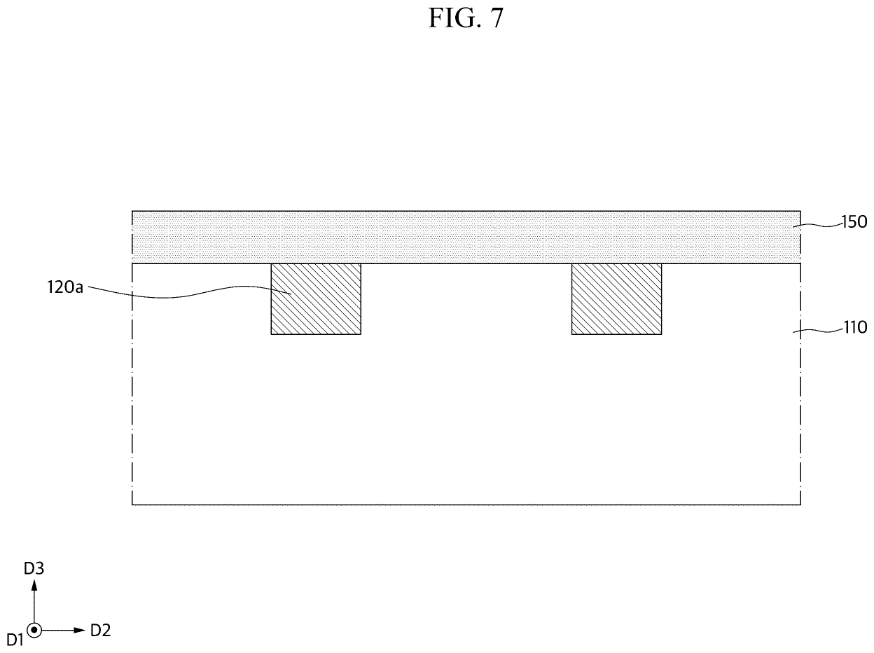

Further, referring to FIG. 7, an insulation layer 150 may be formed. The insulation layer 150 may be placed on the substrate body part 110. The insulation layer 150 may cover the embedding layer 120a.

According to some example embodiments, the insulation layer 150 may include a photosensitive insulating material. For example, the insulation layer 150 may include dry film photoresist. However, the insulation layer 150 is not limited thereto.

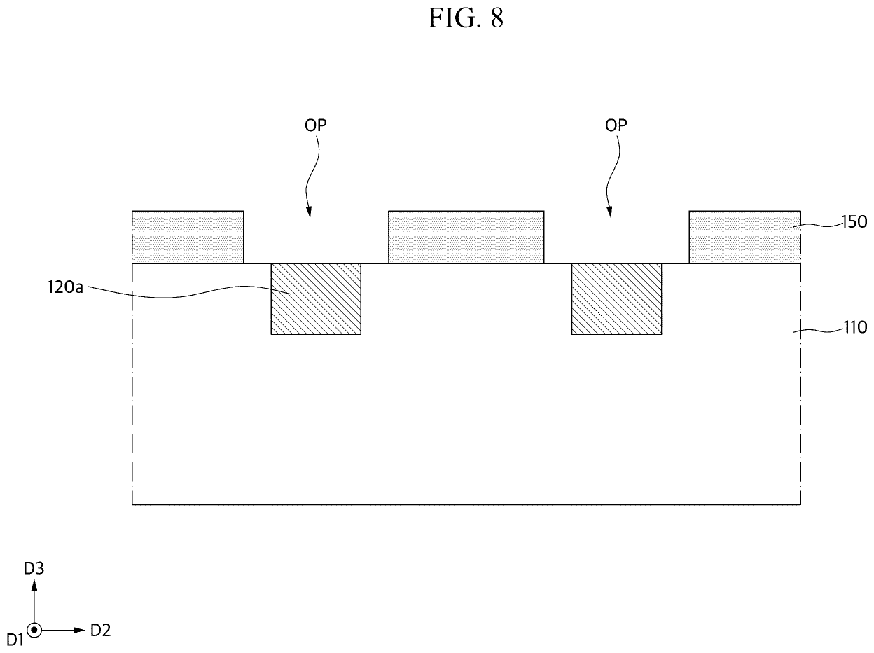

Further, referring to FIG. 8, the insulation layer 150 may be patterned to form an opening part OP. The opening part OP may overlap the embedding layer 120a in the third direction D3. The embedding layer 120a may be exposed through the opening part OP. In the second direction D2, the width of the opening part OP may be greater than the width of the embedding layer 120a.

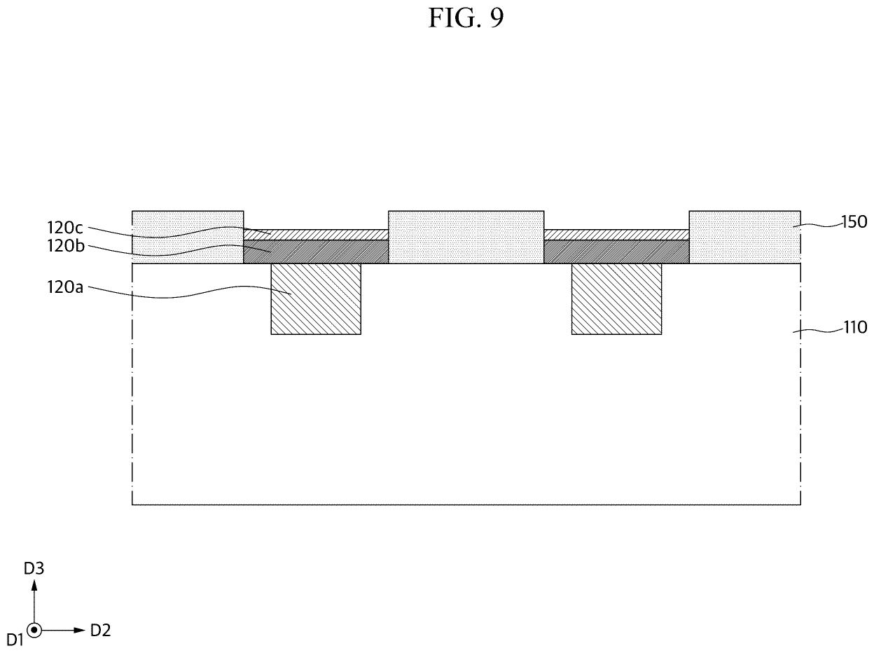

Further, referring to FIG. 9, the first metal layer 120b and the second metal layer 120c may be formed on the embedding layer 120a. The first metal layer 120b and the second metal layer 120c may be formed through a plating process. The first metal layer 120b and the second metal layer 120c may be formed within the opening part OP in FIG. 8, which is formed between the insulation layers 150. The first metal layer 120b and the second metal layer 120c are formed within the opening part OP in FIG. 8, and thus both the side wall of the first metal layer 120b and the side wall of the second metal layer 120c may be in contact with the insulation layer 150. Therefore, the side wall of the first metal layer 120b and the side wall of the second metal layer 120c may be arranged on the same plane.

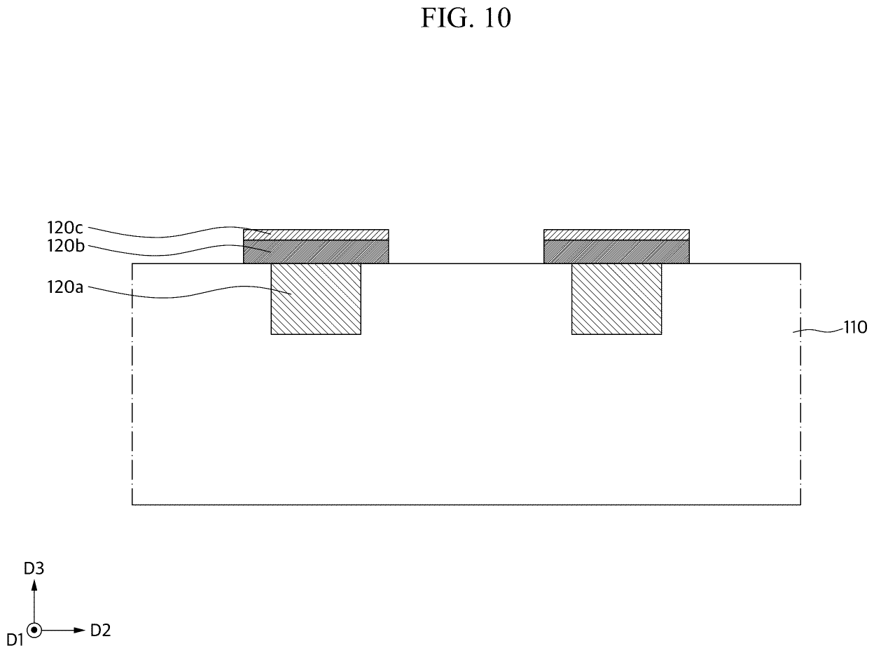

Further, referring to FIG. 10, the insulation layer 150 in FIG. 9 may be removed, exposing the first metal layer 120b and the second metal layer 120c.

Further, referring to FIG. 3, the protection layer 115 may be formed in an area other than the area where the first metal layer 120b and the second metal layer 120c are formed.

According to some example embodiments, the protection layer 115 is formed after the first metal layer 120b and the second metal layer 120c are formed on the embedding layer 120a, and thus the step difference between the upper surface of the embedding layer 120a_US and the upper surface 110US of the substrate body part may be minimized.

In contrast, if the protection layer 115 is formed before forming the first metal layer 120b and the second metal layer 120c on the embedding layer 120a, the etching process is included during the process of forming the protection layer 115, and thus a portion of the embedding layer 120a may be etched. Further, if the step between the upper surface of the embedding layer 120a_US formed by etching a portion of the embedding layer 120a and the upper surface of the substrate body part 110US is filled with the first metal layer 120b, the upper surface of the first metal layer 120b_US is not flat and may be formed convexly toward the top with respect to the substrate body part 110. Therefore, the upper surface of the second metal layer 120c_US formed on the first metal layer 120b may also be formed convexly rather than flat. If the surfaces of the first metal layer 120b and the second metal layer 120c to which the wire is bonded are not flat, wire bonding may be performed unstably.

Meanwhile, before the embedding layer 120a is etched due to the formation of the protection layer 115 and a step is created with the substrate body part 110, if the first metal layer 120b and the second metal layer 120c are formed on the embedding layer 120a using the insulation layer 150, the upper surface of the embedding layer 120a_US, the upper surface of the first metal layer 120b_US, and the upper surface of the second metal layer 120c_US may be formed flat.

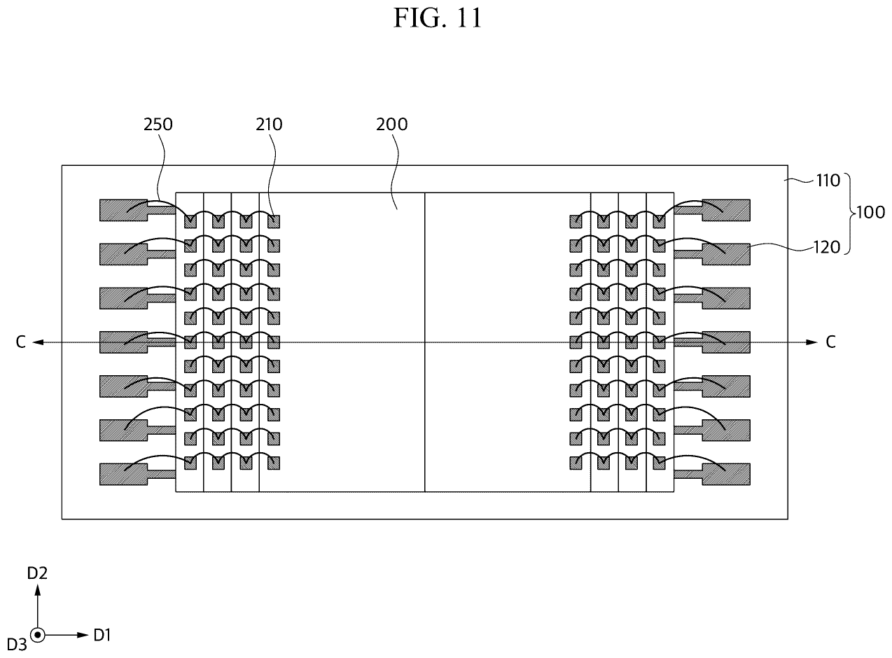

FIG. 11 is a plan view illustrating a semiconductor package according to an example embodiment. FIG. 12 is a cross-sectional view taken along line C-C of FIG. 11. FIGS. 13 and 14 are enlarged views for explaining the portion Q of FIG. 12. For convenience of explanation, the differences from those described with reference to FIGS. 1 to 4 will be mainly explained.

Referring to FIGS. 11 to 14, the semiconductor package may include the package substrate 100, a semiconductor chip 200, a wire 250, and a molding layer 300.

According to some example embodiments, the package substrate 100 may include a redistribution line 140. The protection layer 115 may protect the redistribution line 140 from external impact or moisture.

According to some example embodiments, the redistribution line 140 may be placed within the substrate body part 110. The redistribution line 140 may include a distribution pattern 140a and a distribution via 140b connecting each distribution pattern 140a. For example, the redistribution line 140 may have a multi-layer structure in which two or more distribution patterns 140a and two or more distribution vias 140b are alternately laminated. The distribution patterns 140a may be extended in the first direction D1 or the second direction D2. The distribution patterns 140a may be spaced in the third direction D3. The distribution vias 140b may connect the distribution patterns 140a spaced in the third direction D3.

According to some example embodiments, the connection wirings 130 may electrically connect the distribution patterns 140a and the bonding pads 120. The connection wiring 130 may be a part of the distribution pattern 140a. For example, the distribution pattern 140a including the connection wiring 130 may be electrically connected to the bonding pad 120.

According to some example embodiments, the redistribution line 140 may include an electrically conductive material. For example, the redistribution line 140 may include copper (Cu), aluminum (Al), silver (Ag), tin (Sn), gold (Au), nickel (Ni), lead (Pb), titanium (Ti), or alloys thereof. However, the redistribution line 140 is not limited thereto.

According to some example embodiments, an external connection terminal 15 may be arranged on the bottom surface of the package substrate 100. The external connection terminal 15 may be attached to an external connection pad 10. The external connection terminal 15 may be a solder ball or a solder bump. The external connection terminal 15 may be, for example, spherical or elliptical. However, the external connection terminal 15 is not limited thereto.

According to some example embodiments, the external connection terminal 15 may electrically connect the redistribution line 140 to an external device. Accordingly, the external connection terminal 15 may provide an electrical signal to the redistribution line 140, or provide an electrical signal from the redistribution line 140 to an external device.

According to some example embodiments, the external connection terminal 15 may include at least one of tin (Sn), indium (In), lead (Pb), zinc (Zn), nickel (Ni), gold (Au), silver (Ag), copper (Cu), antimony (Sb), bismuth (Bi), and combinations thereof. However, the present disclosure is not limited thereto.

According to some example embodiments, the semiconductor chip 200 may be placed on the package substrate 100. Each of a plurality of semiconductor chips 200 may include an integrated circuit. The semiconductor chips 200 may be wire-bonded on the package substrate 100. The semiconductor chip 200 may be electrically connected to the package substrate 100 via the wire 250.

According to some example embodiments, the plurality of semiconductor chips 200 may be stacked in a stepwise manner. For example, the plurality of semiconductor chips 200 may stacked in a step-like manner in the first direction D1. FIGS. 11 and 12 illustrate the plurality of semiconductor chips 200, but the present disclosure is not limited thereto.

According to some example embodiments, the semiconductor chips 200 may be memory semiconductor chips. For example, the memory semiconductor chip may be a volatile memory, such as dynamic random access memory (DRAM) and static random access memory (SRAM). Alternatively, the memory semiconductor chip included in the semiconductor chip 200 may be non-volatile memory, such as flash memory, phase-change random access memory (PRAM), magnetic random access memory (MRAM), ferroelectric random access memory (FeRAM) and resistive random access memory (RRAM). However, the present disclosure is not limited thereto. For example, the semiconductor chip 200 may be a logic chip.

According to some example embodiments, the semiconductor chip 200 may include a connection pad 210 and an adhesive layer 205.

According to some example embodiments, the connection pad 210 may be placed on the upper surface of the semiconductor chip 200. The connection pads 210 may be arranged spaced apart from each other on the upper surface of the semiconductor chip 200. For example, the plurality of connection pads 210 may be arranged spaced apart from each other in the second direction D2 on the upper surface of the semiconductor chip 200.

According to some example embodiments, the connection pads 210 may include a pad for transmitting and receiving a power signal or a ground signal and a pad for transmitting and receiving a data signal. In an example embodiment, the semiconductor chip 200 may receive a power signal from the outside through the package substrate 100 and the connection pad 210 connected to the wire 250. In another example embodiment, the semiconductor chip 200 may output a data signal to the outside through the package substrate 100 and the connection pad 210 connected through the wire 250.

According to some example embodiments, the wire 250 may connect the connection pad 210 and the bonding pad 120. Further, the wire 250 may connect the connection pads 210 of each of the plurality of semiconductor chips 200. The semiconductor chip 200 may be electrically connected to the package substrate 100 through the connection pad 210 and the bonding pad 120 that are connected through the wire 250.

According to some example embodiments, the wire 250 may contact the bonding pad 120. For example, the wire 250 may contact the first metal layer 120b and the second metal layer 120c. One end of the wire 250 may be placed within the first metal layer 120b. The end of the wire 250 may be placed on a level that is lower than a level of an upper surface of the bonding pad 120US. The embedding layer 120a may not contact the wire 250.

According to some example embodiments, the upper surface of the bonding pad 120US may be flat or recessed toward the substrate body part 110. Further, the upper surface of the embedding layer 120a may be coplanar with the upper surface of the substrate body part 110, or may be placed on a level that is lower than a level of the upper surface of the substrate body part 110.

According to some example embodiments, the adhesive layer 205 may be placed on the bottom surface of the semiconductor chip 200. The adhesive layer 205 may cover the bottom surface of the semiconductor chip 200. The adhesive layer 205 may be placed between the semiconductor chip 200 and the package substrate 100. The adhesive layer 205 may include a non-conductive film (NCF), a non-conductive paste (NCP), an insulating polymer or an epoxy resin. However, the present disclosure is not limited thereto.

According to some example embodiments, the molding layer 300 may be placed on the package substrate 100. The molding layer 300 may cover the upper surface of the package substrate 100. The molding layer 300 may be placed between the semiconductor chip 200 and the package substrate 100. The molding layer 300 may cover the semiconductor chip 200 on the package substrate 100. The molding layer 300 may cover the upper surface of the semiconductor chip 200 and the side surface of the semiconductor chip 200. The molding layer 300 may surround the wire 250.

According to some example embodiments, the molding layer 300 may include an insulating material. In an example embodiment, the molding layer 300 may include a thermosetting resin such as an epoxy resin or a thermoplastic resin such as a polyimide. In another example embodiment, the molding layer 300 may also include an insulating polymer material such as epoxy molding compound (EMC).

In the above, various embodiments of the present disclosure are described in detail. However, it will be apparent to those with average knowledge in the technical field that scope of rights of this disclosure is not limited thereto, and various modifications and variations are possible without departing from the technical spirit of the present disclosure as set forth in the claims. Further, the above-described example embodiment may be implemented with some elements deleted, and each example embodiment may be implemented in combination with each other.

What is claimed is:

1. A package substrate comprising:
a substrate body part;
a bonding pad, at least a portion of which is embedded in the substrate body part; and
a connection wiring, at least a portion of which is embedded in the substrate body part, and that is connected to the bonding pad in a first direction parallel to a surface of the substrate body part,
wherein the bonding pad comprises:
an embedding layer embedded in the substrate body part;
a first metal layer formed on the embedding layer; and
a second metal layer formed on the first metal layer, and
wherein the first metal layer has an upper surface that is flat.

2. The package substrate of claim 1, wherein a side wall of the first metal layer and a side wall of the second metal layer are coplanar.

3. The package substrate of claim 1, wherein an upper surface of the embedding layer and an upper surface of the substrate body part are coplanar.

4. The package substrate of claim 1, wherein each of the embedding layer, the first metal layer and the second metal layer comprises a different material.

5. The package substrate of claim 4, wherein the embedding layer comprises copper (Cu),
wherein the first metal layer comprises nickel (Ni), and
wherein the second metal layer comprises gold (Au).

6. The package substrate of claim 1, wherein,
in a second direction that is parallel to the surface of the substrate body part and intersects the first direction,
a maximum width of the bonding pad is greater than a maximum width of the connection wiring.

7. The package substrate of claim 6, wherein the bonding pad comprises:
a connection part that is connected to the connection wiring, and has a width that is identical to a width of the connection wiring in the second direction; and
a bonding part that is connected to the connection wiring with the connection part in between, and has a width that is greater than a width of the connection part in the second direction, and
wherein a portion of the first metal layer and a portion the second metal layer of the bonding part have a width in the first direction that is greater than a width in the second direction.

8. The package substrate of claim 1, wherein,
in a second direction that is parallel to the surface of the substrate body part and intersects the first direction, the first metal layer and the second metal layer have a width that is greater than a width of the embedding layer.

9. The package substrate of claim 1, wherein the first metal layer has a thickness that is greater than a thickness of the second metal layer.

10. The package substrate of claim 1, further comprising a protection layer disposed on the substrate body part, and includes an opening that exposes the second metal layer.

11. The package substrate of claim 10, wherein, based on the upper surface of the substrate body part, the protection layer has an upper surface that is disposed at a level that is higher than a level of an upper surface of the second metal layer.

12. The package substrate of claim 10, wherein the protection layer comprises solder resist.

13. A semiconductor package comprising:
a package substrate; and
a semiconductor chip that is wire-bonded on the package substrate,
wherein the package substrate comprises:
a substrate body part; and
a bonding pad disposed on the substrate body part and connected to the semiconductor chip by a wire,
wherein the bonding pad comprises:
an embedding layer embedded in the substrate body part;
a first metal layer on the embedding layer; and
a second metal layer on the first metal layer, and
wherein a side wall of the first metal layer and a side wall of the second metal layer are coplanar.

14. The semiconductor package of claim 13, wherein the semiconductor chip comprises memory.

15. The semiconductor package of claim 13, wherein the wire has one end that contacts the first metal layer.

16. The semiconductor package of claim 13, wherein the embedding layer has an upper surface that is disposed at a level that is lower than a level of an upper surface of the substrate body part, and
wherein an upper surface of the first metal layer and an upper surface of the second metal layer are indented toward the embedding layer.

17. The semiconductor package of claim 13, wherein an upper surface of the embedding layer is coplanar with an upper surface of the substrate body part, or is disposed at a level that is lower than a level of the upper surface of the substrate body part.

18. The semiconductor package of claim 13, wherein a plurality of bonding pads are disposed on the substrate body part in a first direction, and
in the first direction, a width of the first metal layer and a width of the second metal layer are greater than a width of the embedding layer.

19. The semiconductor package of claim 13, wherein the package substrate further comprises a protection layer disposed on the substrate body part, and includes an opening that exposes the second metal layer,
wherein the semiconductor chip is disposed on the protection layer, and
wherein the protection layer has an upper surface that is disposed at a level that is higher than a level of an upper surface of the second metal layer.

20. A package substrate comprising:
a substrate body part;
a connection wiring embedded in the substrate body part;
a bonding pad that is connected to the connection wiring in a first direction that is parallel to a surface of the substrate body part; and
a protection layer that is disposed on the substrate body part, and includes an opening that exposes an upper surface of the bonding pad,
wherein the bonding pad comprises:
an embedding layer embedded in the substrate body part;
a first metal layer on the embedding layer; and
a second metal layer on the first metal layer,
wherein the protection layer has an upper surface that is disposed at a level that is higher than a level of an upper surface of the second metal layer,
wherein an upper surface of the first metal layer and an upper surface of the second metal layer are flat,
wherein, in a second direction that is parallel to the surface of the substrate body part and intersects the first direction, a width of the first metal layer and a width of the second metal layer are identical, and
wherein the width of the first metal layer is greater than a width of the embedding layer in the second direction.
